(19) United States
(12) Patent Application Publication
(10) Pub. No.: US 2023/0420498 A1
(43) Pub. Date: Dec. 28, 2023

(54) Enhancement High Electron Mobility Transistor and Manufacturing Method Thereof

(71) Applicant: Richtek Technology Corporation, Zhubei City (TW)

(72) Inventor: Han-Chung Tai, Hsinchu (TW)

(21) Appl. No.: 18/164,571

(22) Filed: Feb. 4, 2023

(30) Foreign Application Priority Data
Jun. 23, 2022 (TW) 111123384

(51) Int. Cl. H01L 29/06; H01L 29/778; H01L 29/40; H01L 29/66

(52) U.S. Cl. CPC H01L 29/0642; H01L 29/7786; H01L 29/7783; H01L 29/402; H01L 29/0649; H01L 29/66462; H01L 29/2003

(57) ABSTRACT

A high electron mobility transistor includes: a substrate; a first gallium nitride (GaN) layer, which is formed on the substrate; a first aluminum gallium nitride (AlGaN) layer, which is formed on and in contact with the first GaN layer, wherein the first AlGaN layer has a trench; two insulation sidewalls, which are in contact with and completely overlay two inner sidewalls of the trench, respectively; a P-type GaN layer, which is formed on and in contact with the first AlGaN layer, wherein a part of the P-type GaN layer fills into the trench; a gate, which is formed on and in contact with the P-type GaN layer, and is configured to receive a gate voltage, for turning ON or OFF the enhancement HEMT; and a source and a drain, which are located outside two sides of the gate, respectively.

### CROSS REFERENCE

The present invention claims priority to TW 111123384 filed on Jun. 23, 2022.

### BACKGROUND OF THE INVENTION

### Field of Invention

The present invention relates to an enhancement high electron mobility transistor (HEMT) and a manufacturing method thereof; particularly, it relates to such enhancement HEMT and such manufacturing method of the enhancement HEMT capable of reducing dynamic conduction resistance (Ron) effect.

### Description of Related Art

Please refer to FIG. 1, which shows a cross-section view of a conventional enhancement high electron mobility transistor (HEMT) 100. As shown in FIG. 1, a gallium nitride (GaN) layer 12 is formed on the substrate 11, and the enhancement HEMT 100 further comprises: an aluminum gallium nitride (AlGaN) layer, a P-type GaN (pGaN) layer 15, a gate 16, a source 17 and a drain 18. A 2-dimensional electron gas (2DEG) is formed at a junction between the GaN layer 12 and the AlGaN layer 13, as indicated by the circlar electron symbols).

As shown in FIG. 1, the GaN layer 12 and the AlGaN layer 13 are connected to each other, and there is a stress at the junction between the GaN layer 12 and the AlGaN layer 13, causing the energy bands of the energy levels of the GaN layer 12 and the AlGaN layer 13 to be distorted, so that electrons are confined in electron wells. Because these confined electrons can reduce Coulomb scattering, electron mobility in the 2DEG is enhanced. Consequently, when the enhancement HEMT 100 is in ON operation (i.e., when a positive voltage greater than a threshold voltage is applied to the gate 16, the enhancement HEMT 100 is turned ON), as compared to a general semiconductor device, the enhancement HEMT 100 has a faster operation speed due to the high electron mobility. As compared to a silicon-made semiconductor device, particularly when the semiconductor device which is used as a power switch, the enhancement HEMT 100 has advantages of low Ron, high breakdown voltage and high switching speed.

The prior art enhancement HEMT 100 shown in FIG. 1 has the following drawback. In the enhancement HEMT 100, the pGaN layer 15 is doped with magnesium (Mg), and magnesium can diffuse to pollute the AlGaN layer 13, resulting in an issue of dynamic Ron effect. That is, while the enhancement HEMT 100 is in ON operation, Ron will increase unstably, whereas, while the enhancement HEMT 100 is in OFF operation, Ron will restore to an initial level, thus reducing the reliability of the enhancement HEMT 100.

In view of the above, to overcome the drawback in the prior art, the present invention proposes an enhancement HEMT and a manufacturing method of the enhancement HEMT, which are capable of mitigating the dynamic Ron effect and improving the reliability of the enhancement HEMT.

### SUMMARY OF THE INVENTION

From one perspective, the present invention provides an enhancement high electron mobility transistor (HEMT), comprising: a substrate; a first gallium nitride (GaN) layer, which is formed on the substrate; a first aluminum gallium nitride (AlGaN) layer, which is formed on and in contact with the first GaN layer, wherein the first AlGaN layer has a trench, wherein the trench does not penetrate through the AlGaN layer; two insulation sidewalls, which are in contact with and completely overlay two inner sidewalls of the trench, respectively; a P-type GaN layer, which is formed on and in contact with the first AlGaN layer, wherein a part of the P-type GaN layer fills into the trench; a gate, which is formed on and in contact with the P-type GaN layer, and is configured to receive a gate voltage, so as to turn ON or turn OFF the enhancement HEMT; and a source and a drain, which are located outside two sides of the gate, respectively, wherein the source and the drain penetrate through the first AlGaN layer, so that the source and the drain are in contact with the first GaN layer.

From another perspective, the present invention provides a manufacturing method of an enhancement HEMT, comprising steps of: providing a substrate; forming a first gallium nitride (GaN) layer on the substrate; forming a first aluminum gallium nitride (AlGaN) layer on the first GaN layer, wherein the first AlGaN layer is in contact with the first GaN layer; forming a trench in the first AlGaN layer, wherein the trench does not penetrate through the AlGaN layer; forming an insulation sidewall via a self-alignment process step, wherein the insulation sidewall is in contact with and completely overlay two inner sidewalls of the trench; forming a P-type GaN layer on the first AlGaN layer, wherein the P-type GaN layer is in contact with the first AlGaN layer, wherein a part of the P-type GaN layer fills into the trench; forming a gate on the P-type GaN layer, wherein the gate is in contact with the P-type GaN layer, wherein the gate is configured to receive a gate voltage, so as to turn ON or turn OFF the enhancement HEMT; and forming a source and a drain outside two sides of the gate, respectively, wherein the source and the drain penetrate through the first AlGaN layer, so that the source and the drain are in contact with the first GaN layer.

In one embodiment, the enhancement HEMT further comprises: a dielectric layer, which is formed on and in contact with the first AlGaN layer, wherein the dielectric layer lies between the P-type GaN layer and the drain in a channel direction; and an adjustment drain, which is formed on and in contact with the dielectric layer; wherein the dielectric layer and the adjustment drain entirely overlap each other, to form a stacked structure, and wherein a length of the stacked structure along the channel direction and a gap width between the stacked structure and the gate are determined according to a required operation reliability of the enhancement HEMT.

In one embodiment, the enhancement HEMT further comprises: a second AlGaN layer, which is formed below and in contact with the first GaN layer; and a second GaN layer, which is formed below and in contact with the second AlGaN layer.

In one embodiment, the source and the drain do not penetrate through the second AlGaN layer but stay in the first AlGaN layer, wherein a thickness of the second AlGaN layer is controlled so as to avoid generating a two-dimensional electron gas (2DEG) between the second AlGaN layer and the second GaN layer.

In one embodiment, the source and drain further penetrate through the second AlGaN layer, so that the source and drain are in contact with the second AlGaN layer, whereby a 2DEG is generated between the second AlGaN layer and the second GaN layer by controlling a thickness of the second AlGaN layer.

In one embodiment, the two insulation sidewalls include aluminum oxide (Al₂O₃), and wherein the two insulation sidewalls are formed via a self-alignment process step.

In one embodiment, the dielectric layer includes P-type GaN, and wherein the dielectric layer and P-type GaN layer are formed via a same process step.

In one embodiment, the adjustment drain and the drain are electrically connected to each other.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-section view of a conventional enhancement high electron mobility transistor (HEMT) 100.

FIG. 2 shows a cross-section view of an enhancement HEMT 200 according to an embodiment of the present invention.

FIG. 3 shows a cross-section view of an enhancement HEMT 300 according to an embodiment of the present invention.

FIG. 4 shows a cross-section view of an enhancement HEMT 400 according to an embodiment of the present invention.

FIG. 5 shows a cross-section view of an enhancement HEMT 500 according to an embodiment of the present invention.

FIG. 6 shows a cross-section view of an enhancement HEMT 600 according to an embodiment of the present invention.

FIG. 7A to FIG. 7H show cross-section views of a manufacturing method of the enhancement HEMT 600 according to an embodiment of the present invention

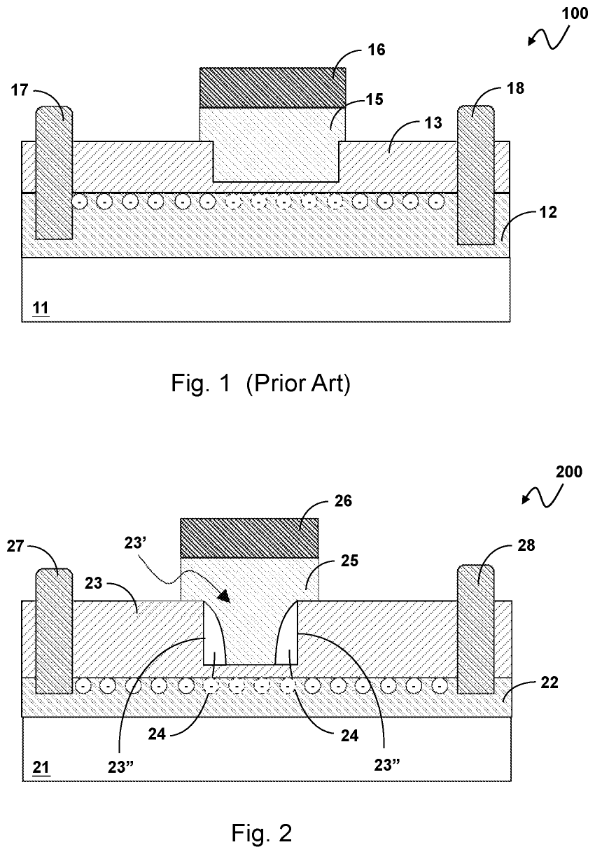

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

Please refer to FIG. 2, which shows a cross-section view of an enhancement HEMT 200 according to an embodiment of the present invention. As shown in FIG. 2, the enhancement HEMT 200 comprises: a substrate 21, a first gallium nitride (GaN) layer 22, a first aluminum gallium nitride (AlGaN) layer 23, two insulation sidewalls 24, a P-type GaN layer 25, a gate 26, a source 27 and a drain 28.

The substrate 21 is, for example but not limited to, a silicon substrate, a silicon carbide substrate, a sapphire substrate or any other type of semiconductor substrate. The first GaN layer 22 is formed on the substrate 21. The first AlGaN layer 23 is formed on and in contact with the first GaN layer 22, wherein the first AlGaN layer 23 has a trench 23′, wherein the trench 23′ does not penetrate through the AlGaN layer 23. The trench 23′ serves to control a thickness of the AlGaN layer 23 which is vertically below the trench 23′. By means of the PN junction formed between the P-type GaN layer 25 and the first AlGaN layer 23/the first GaN layer 22, a two-dimensional electron gas (2DEG) channel is depleted to turn OFF the 2DEG channel, thereby realizing positive voltage control of the enhancement HEMT 200. That is, in a case where a voltage applied to the gate 26 does not exceed a threshold voltage, an electron channel will not be formed (as indicated by dashed line electrons) in the junction between the first AlGaN layer 23 vertically below the trench 23′ and the first GaN layer 22, whereby the enhancement HEMT 200 is OFF. On the other hand, in a case where a voltage applied onto the gate 26 exceeds the threshold voltage, an electron channel will be formed, whereby the enhancement HEMT 200 is turned ON.

The two insulation sidewalls 24 are in contact with and completely overlay two inner sidewalls 23″ of the trench 23′, respectively. The two insulation sidewalls 24 are electrically insulative. Besides, the two insulation sidewalls 24 serve to prevent magnesium (Mg) in the P-type GaN layer 25 from diffusing to the first AlGaN layer 23 from the two inner sidewalls 23″ of the trench 23′, so as to mitigate the dynamic Ron effect and improve the reliability of the enhancement HEMT 200. The two insulation sidewalls 24 are made of (or substantially include) aluminum oxide (Al₂O₃). The two insulation sidewalls 24 are formed via for example a self-alignment process step, which forms the two insulation sidewalls 24 in contact with the two inner sidewalls 23″ of the trench 23′.

The P-type GaN layer 25 is formed on and in contact with the first AlGaN layer 23, wherein a part of the P-type GaN layer 25 fills into the trench 23′. The gate 26 is formed on and in contact with the P-type GaN layer 25, wherein the gate 26 is configured to receive a gate voltage, to turn ON or turn OFF the enhancement HEMT 200. The source 27 and the drain 28 are located outside two sides of the gate 26, respectively, wherein the source 27 and the drain 28 penetrate through the first AlGaN layer 23, so that the source 27 and the drain 28 are in contact with the first GaN layer 22.

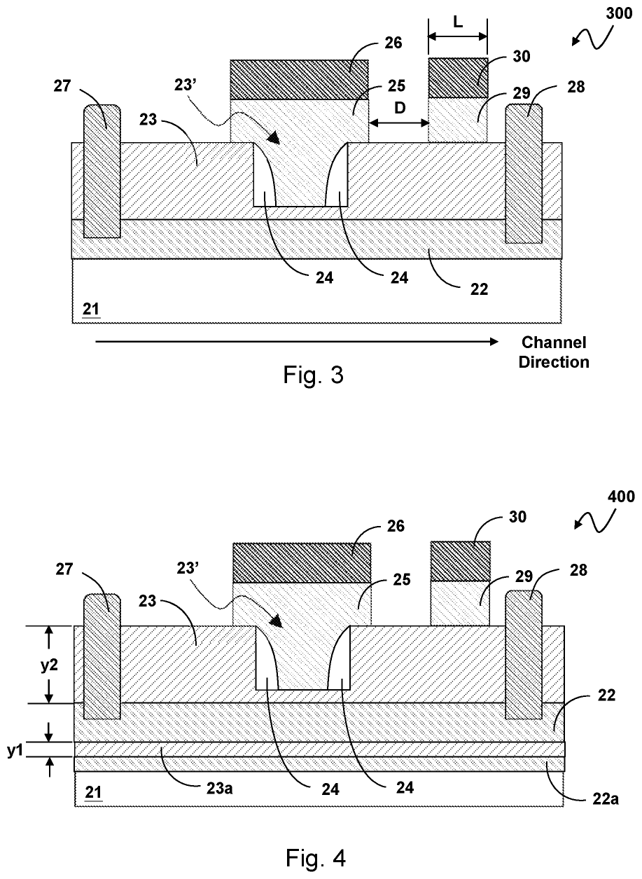

Please refer to FIG. 3, which shows a cross-section view of an enhancement HEMT 300 according to an embodiment of the present invention. The substrate 21, the first gallium nitride (GaN) layer 22, the first aluminum gallium nitride (AlGaN) layer 23, two insulation sidewalls 24, the P-type GaN layer 25, the gate 26, the source 27 and the drain 28 of this embodiment shown in FIG. 3 is similar to the substrate 21, the first gallium nitride (GaN) layer 22, the first aluminum gallium nitride (AlGaN) layer 23, two insulation sidewalls 24, the P-type GaN layer 25, the gate 26, the source 27 and the drain 28 of the embodiment shown in FIG. 2, so the details thereof are not redundantly repeated here. As compared to the enhancement HEMT 200, the enhancement HEMT 300 further comprises: a dielectric layer 29 and an adjustment drain 30.

The dielectric layer 29 is formed on and in contact with the first AlGaN layer 23. And, the dielectric layer 29 lies between the P-type GaN layer 25 and the drain 28 in a channel direction (as indicated by the direction of the solid arrow in FIG. 3). The adjustment drain 30 is formed on and in contact with the dielectric layer 29. The dielectric layer 29 and the adjustment drain 30 entirely overlap each other, to form a stacked structure, wherein a length L of the stacked structure along the channel direction and a gap width D between the stacked structure and the gate 26 are determined according to the required operation reliability of the enhancement HEMT 300.

In one embodiment, the material of the dielectric layer 29 is P-type GaN, and the dielectric layer 29 and P-type GaN layer 25 are formed via a same process step, to reduce manufacturing cost. The dielectric layer 29 can be made of another dielectric material, such as silicone dioxide (SiO₂) or silicon nitride (Si₃N₄). In one embodiment, the adjustment drain 30 and the drain 28 are electrically connected to each other. In a general application wherein the voltage applied to the drain 28 is higher than the voltage applied to the source 27, the electrical connection of the adjustment drain 30 and the drain 28 can regulate the channel electrical field distribution when the enhancement HEMT 300 is in ON operation, so as to mitigate the dynamic Ron effect and enhance the reliability of the enhancement HEMT 300. Furthermore, the length L and the gap width D can be adjusted according to the dynamic Ron effect, so as to optimize the reliability of the enhancement HEMT 300.

Please refer to FIG. 4, which shows a cross-section view of an enhancement HEMT 400 according to an embodiment of the present invention. The substrate 21, the first gallium nitride (GaN) layer 22, the first aluminum gallium nitride (AlGaN) layer 23, two insulation sidewalls 24, the P-type GaN layer 25, the gate 26, the source 27, the drain 28, the dielectric layer 29 and the adjustment drain 30 of this embodiment shown in FIG. 4 is similar to the substrate 21, the first gallium nitride (GaN) layer 22, the first aluminum gallium nitride (AlGaN) layer 23, two insulation sidewalls 24, the P-type GaN layer 25, the gate 26, the source 27 and the drain 28, the dielectric layer 29 and the adjustment drain 30 of the embodiment shown in FIG. 3, so the details thereof are not redundantly repeated here. As compared to the enhancement HEMT 300, the enhancement HEMT 400 further comprises: a second GaN layer 22a and a second AlGaN layer 23a.

The second AlGaN layer 23a is formed below and in contact with the first GaN layer 22, wherein the first GaN layer 22 entirely overlays the second AlGaN layer 23a. The second GaN layer 22a is formed below and in contact with the second AlGaN layer 23a, wherein the second AlGaN layer 23a entirely overlays the second GaN layer 22a. In this embodiment, the source 27 and the drain do not penetrate the second AlGaN layer 23a but stay in the first AlGaN layer 23. The thickness y1 of the second AlGaN layer 23a can be adjusted to avoid forming a two-dimensional electron gas (2DEG) between the second AlGaN layer 23a and the second GaN layer 22a. The formation of the second GaN layer 22a and the second AlGaN layer 23a can improve the crystal defects of the junction between the first GaN layer 22 and the first AlGaN layer 23, thereby further enhancing the reliability of the enhancement HEMT 400. Additionally, the reliability of the enhancement HEMT 400 can be enhanced by adjusting the thickness y2 of the first AlGaN layer 23.

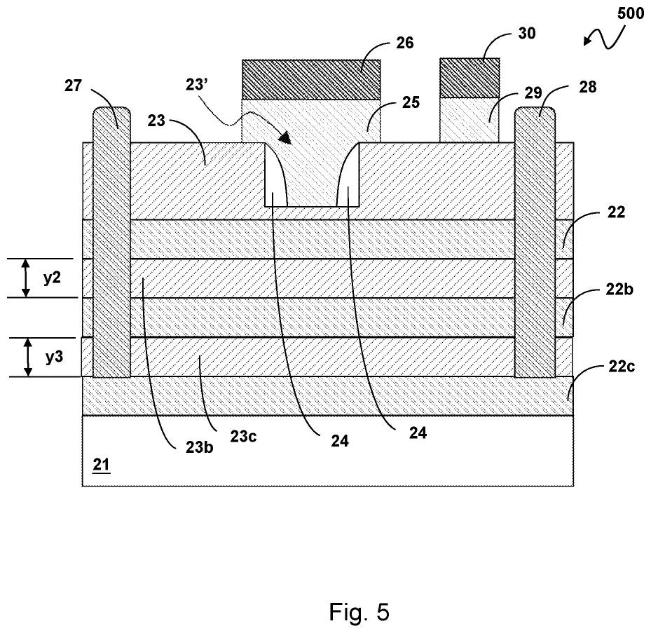

Please refer to FIG. 5, which shows a cross-section view of an enhancement HEMT 500 according to an embodiment of the present invention. The substrate 21, the first gallium nitride (GaN) layer 22, the first aluminum gallium nitride (AlGaN) layer 23, two insulation sidewalls 24, the P-type GaN layer 25, the gate 26, the source 27, the drain 28, the dielectric layer 29 and the adjustment drain 30 of this embodiment shown in FIG. 5 is similar to the substrate 21, the first gallium nitride (GaN) layer 22, the first aluminum gallium nitride (AlGaN) layer 23, two insulation sidewalls 24, the P-type GaN layer 25, the gate 26, the source 27 and the drain 28, the dielectric layer 29 and the adjustment drain 30 of the embodiment shown in FIG. 4, so the details thereof are not redundantly repeated here. As compared to the enhancement HEMT 400, the enhancement HEMT 500 further comprises: second GaN layers 22b and 22c and second AlGaN layers 23b and 23c.

The second AlGaN layer 23b is formed below and in contact with the first GaN layer 22, wherein the first GaN layer 22 entirely overlays the second AlGaN layer 23b. The second AlGaN layer 22b is formed below and in contact with the second AlGaN layer 23b, wherein the second AlGaN layer 23b entirely overlays the second AlGaN layer 22b. The second AlGaN layer 23c is formed below and in contact with the second AlGaN layer 22b, wherein the second AlGaN layer 22b entirely overlays the second AlGaN layer 23c. The second AlGaN layer 22c is formed below and in contact with the second AlGaN layer 23c, wherein the second AlGaN layer 23c entirely overlays the second GaN layer 22c. In this embodiment, the source 27 and the drain penetrate the first AlGaN layer 23, the first GaN layer 22, the second AlGaN layer 23b, the second GaN layer 22b and the second GaN layer 22c, and stay in the second GaN layer 22c. The thickness y2 of the second AlGaN layer 23b and the thickness y3 of the second AlGaN layer 23c can be adjusted to form a 2DEG between the second AlGaN layer 23b and the second GaN layer 22b, and to form a 2DEG between the second AlGaN layer 23c and the second GaN layer 22c, so as to form multiple channels in the enhancement HEMT 500. The formation of the multiple channels can expand the electrical field distribution downward, so that the electrical field distribution becomes more uniform, thus enhancing the reliability of the enhancement HEMT 500.

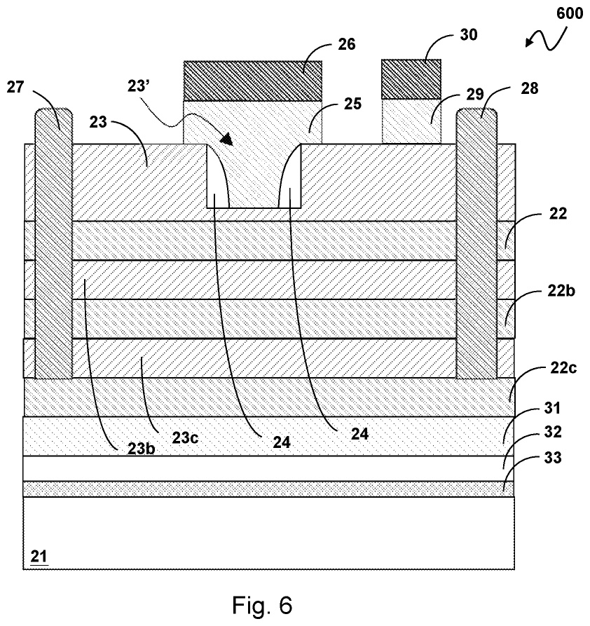

Please refer to FIG. 6, which shows a cross-section view of an enhancement HEMT 600 according to an embodiment of the present invention. The substrate 21, the first gallium nitride (GaN) layer 22, the first aluminum gallium nitride (AlGaN) layer 23, two insulation sidewalls 24, the P-type GaN layer 25, the gate 26, the source 27, the drain 28, the dielectric layer 29, the adjustment drain 30, second GaN layers 22b and 22c and second AlGaN layers 23b and 23c of this embodiment shown in FIG. 6 is similar to the substrate 21, the first gallium nitride (GaN) layer 22, the first aluminum gallium nitride (AlGaN) layer 23, two insulation sidewalls 24, the P-type GaN layer 25, the gate 26, the source 27 and the drain 28, the dielectric layer 29, the adjustment drain 30, second GaN layers 22b and 22c and second AlGaN layers 23b and 23c of the embodiment shown in FIG. 5, so the details thereof are not redundantly repeated here. As compared to the enhancement HEMT 500, the enhancement HEMT 600 further comprises: a GaN buffer layer 31, an AlGaN buffer layer 32 and an AIN seed layer 33. The AIN seed layer 33, the AlGaN buffer layer 32 and the GaN buffer layer 31 are sequentially stacked on the substrate 21, so as to provide a basis layer for forming following other regions thereon.

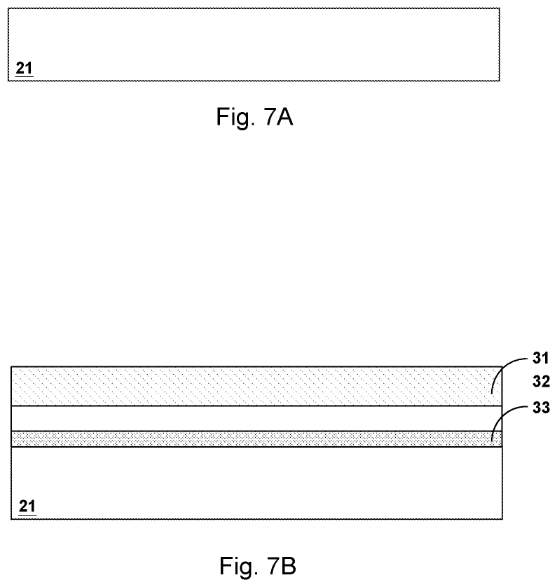

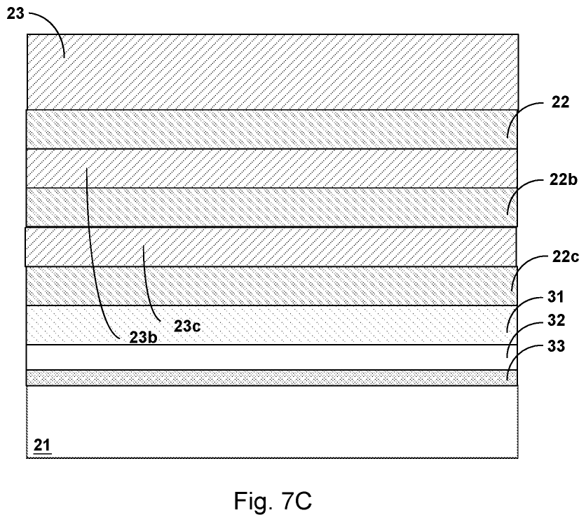

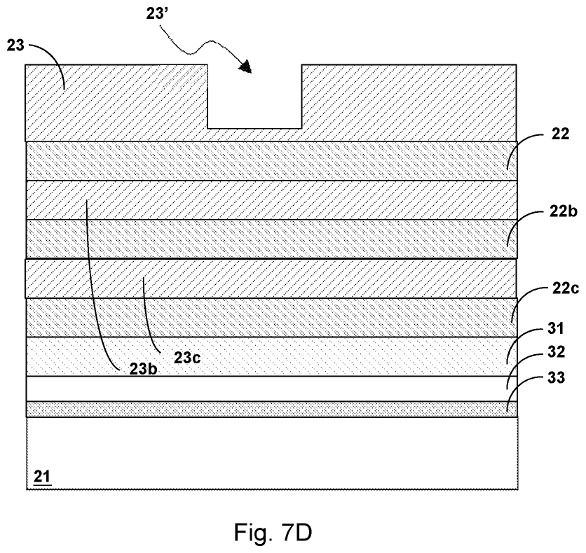

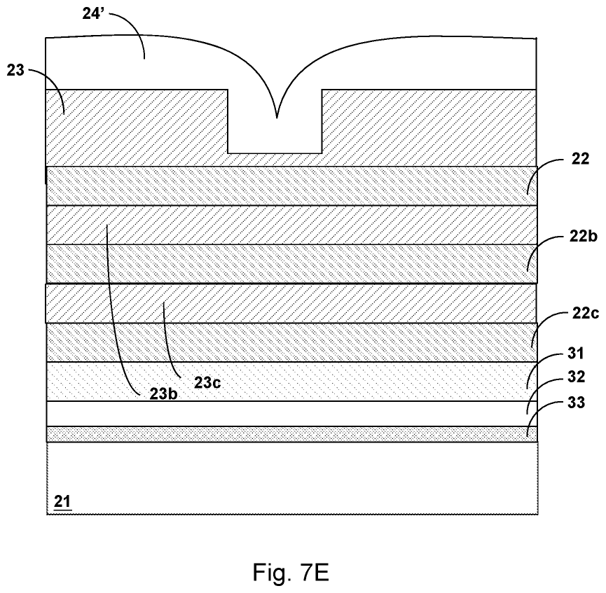

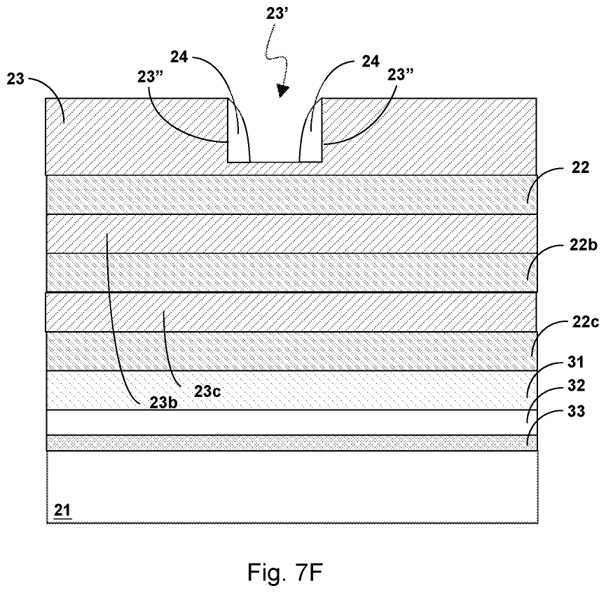

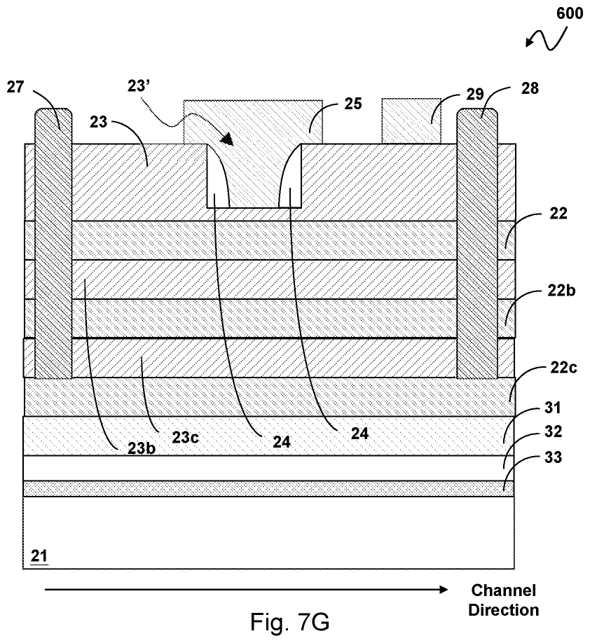

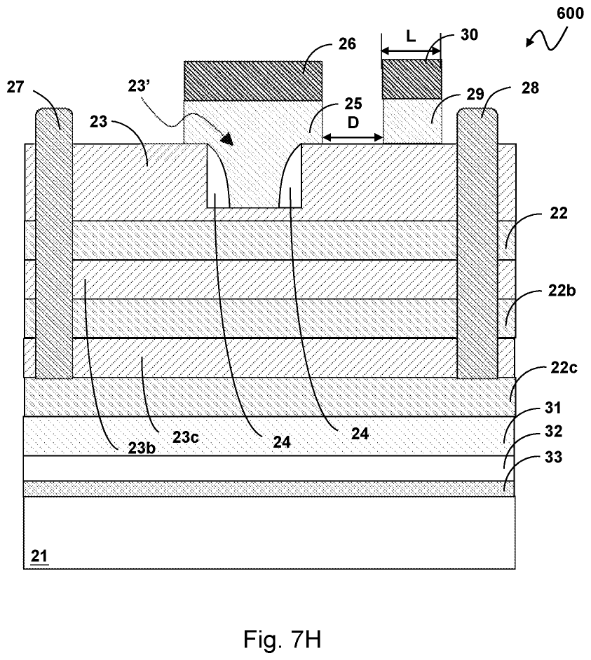

Please refer to FIG. 7A to FIG. 7H, which show cross-section views of a manufacturing method of an enhancement HEMT 600 according to an embodiment of the present invention. As shown in FIG. 7A, first, a substrate 21 is provided. The substrate 21 is, for example but not limited to, a silicon substrate, a silicon carbide substrate, a sapphire substrate or any other type semiconductor substrate.

Next, referring to FIG. 7B, an AIN seed layer 33, an AlGaN buffer layer 32 and a GaN buffer layer 31 are sequentially stacked on the substrate 21, so as to provide a basis layer for forming following other regions thereon. The AIN seed layer 33, the AlGaN buffer layer 32 and the GaN buffer layer 31 can be formed by process steps which are well known to those skilled in the art, so the details thereof are not redundantly explained here.

Next, referring to FIG. 7C, a second GaN layer 22c, a second AlGaN layer 23c, a second GaN layer 22b, a second AlGaN layer 23b, a first GaN layer 22 and a first AlGaN layer 23 are sequentially stacked on the GaN buffer layer 31. The first GaN layer 22 is formed below and in contact with the first AlGaN layer 23, wherein the first AlGaN layer 23 entirely overlays the first GaN layer 22. The second AlGaN layer 23b is formed below and in contact with the first GaN layer 22, wherein the first GaN layer 22 entirely overlays second AlGaN layer 23b. The second GaN layer 22b is formed below and in contact with the second AlGaN layer 23b, wherein the second AlGaN layer 23b entirely overlays the second GaN layer 22b. The second GaN layer 22b is formed below and in contact with the second AlGaN layer 23c, wherein the second GaN layer 22b entirely overlays the second AlGaN layer 23c. The second GaN layer 22c is formed below and in contact with the second AlGaN layer 23c, wherein the second AlGaN layer 23c entirely overlays the second GaN layer 22c. The thickness of the second AlGaN layer 23b and the thickness of the second AlGaN layer 23c are adjusted to form a 2DEG between the second AlGaN layer 23b and the second GaN layer 22b, and to form a 2DEG between the second AlGaN layer 23c and the second GaN layer 22c, so as to form multiple channels in the enhancement HEMT 600.

Next, referring to FIG. 7D, a trench 23′ is formed in the AlGaN layer 23 by, for example but not limited to, a lithography process step, wherein the lithography process step is well known to those skilled in the art, so the details thereof are not redundantly explained here. The first AlGaN layer 23 is formed on and in contact with the first GaN layer 22. The trench 23′ does not penetrate through the AlGaN layer 23. The trench 23′ serves to control the thickness of the AlGaN layer 23 which is vertically below the trench 23′. In device operation, by means of the PN junction formed between the P-type GaN layer 25 and the first AlGaN layer 23/the first GaN layer 22, a two-dimensional electron gas (2DEG) channel is depleted to turn OFF the 2DEG channel, thereby realizing positive voltage control of the enhancement HEMT 600. That is, in a case where a voltage applied to the gate 26 does not exceed a threshold voltage, an electron channel will not be formed (as indicated by dashed line electrons in FIG. 2) in the junction between the first AlGaN layer 23 vertically below the trench 23′ and the first GaN layer 22, whereby the enhancement HEMT 600 is OFF. On the other hand, in a case where a voltage applied onto the gate 26 exceeds the threshold voltage, an electron channel will be formed, whereby the enhancement HEMT 600 is turned ON.

Next, referring to FIG. 7E, an insulation layer 24′ are formed by, for example but not limited to, a deposition process step. The insulation layer 24′ is electrically insulative, wherein the insulation layer 24′ is made of (or substantially includes) aluminum oxide (Al₂O₃), silicone dioxide (SiO₂) or silicon nitride (Si₃N₄).

Next, referring to FIG. 7F, two insulation sidewalls 24 are formed via a self-alignment process step, wherein the self-alignment process step includes an anisotropic etching process step. To be more specific, in the anisotropic etching process step, other than the part of the insulation layer 24′ which is in contact with and completely overlays the two inner sidewalls 23″ of the trench 23′, the rest part of the insulation layer 24′ is removed to form the two insulation sidewalls 24 as shown in FIG. 7F. The two insulation sidewalls 24 are electrically insulative. Besides, the two insulation sidewalls 24 serve to prevent magnesium (Mg) in the P-type GaN layer 25 from diffusing to the first AlGaN layer 23 from the two inner sidewalls 23″ of the trench 23′, thus mitigating the dynamic Ron effect and improving the reliability of the enhancement HEMT 600. The two insulation sidewalls 24 are made of (or substantially include) aluminum oxide (Al₂O₃). The two insulation sidewalls 24 are formed to be in connection with the two inner sidewalls 23″ of the trench 23′ via for example the aforementioned self-alignment process step.

Next, referring to FIG. 7G, a P-type GaN layer 25 is formed on and in contact with the first AlGaN layer 23, wherein a part of the P-type GaN layer 25 fills into the trench 23′. In this embodiment, while the P-type GaN layer 25 is formed, a dielectric layer 29 is concurrently formed on and in contact with the first AlGaN layer 23. The dielectric layer 29 lies between the P-type GaN layer 25 and the drain 28 (which is to be formed by a subsequent process step) in a channel direction (as indicated by the direction of the solid arrow in FIG. 7G).

Next, referring to FIG. 7H, the gate 26 is formed on and in contact with the P-type GaN layer 25, and the gate 26 is configured to receive a gate voltage, so as to turn ON or turn OFF the enhancement HEMT 600. In this embodiment, while the gate 26 is formed, the adjustment drain 30 is concurrently formed. The adjustment drain 30 is formed on and in contact with the dielectric layer 29. The dielectric layer 29 and the adjustment drain 30 entirely overlap each other, to form a stacked structure, wherein a length L of the stacked structure along the channel direction and a gap width D between the stacked structure and the gate 26 are determined according to the required operation reliability of the enhancement HEMT 600. In one embodiment, the adjustment drain 30 and the drain 28 are electrically connected to each other. In a general application wherein a voltage applied to the drain 28 is higher than a voltage applied to the source 27, the electrical connection of the adjustment drain 30 and the drain 28 can regulate the channel electrical field distribution when the enhancement HEMT 600 is in ON operation, so as to mitigate the dynamic Ron effect and the enhance reliability of the enhancement HEMT 600. Furthermore, the length L and the gap width D can be adjusted according to the dynamic Ron effect, so as to optimize the reliability of the enhancement HEMT 600.

Please refer to FIG. 7H. The source 27 and the drain 28 are formed and located outside two sides of the gate 26, wherein the source 27 and the drain 28 penetrate the first AlGaN layer 23, the first GaN layer 22, the second AlGaN layer 23b, the second GaN layer 22b and the second AlGaN layer 23c, and stay in the second GaN layer 22c. The source 27 and the drain 28 are electrically connected to each other when the enhancement HEMT 600 is in ON operation.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a threshold voltage adjustment region'a metal silicide layer may be added. For another example, the lithography process step is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. An enhancement high electron mobility transistor (HEMT), comprising:
a substrate;
a first gallium nitride (GaN) layer, which is formed on the substrate;
a first aluminum gallium nitride (AlGaN) layer, which is formed on and in contact with the first GaN layer, wherein the first AlGaN layer has a trench, wherein the trench does not penetrate through the AlGaN layer;
two insulation sidewalls, which are in contact with and completely overlay two inner sidewalls of the trench, respectively;
a P-type GaN layer, which is formed on and in contact with the first AlGaN layer, wherein a part of the P-type GaN layer fills into the trench;
a gate, which is formed on and in contact with the P-type GaN layer, and is configured to receive a gate voltage, so as to turn ON or turn OFF the enhancement HEMT; and
a source and a drain, which are located outside two sides of the gate, respectively, wherein the source and the drain penetrate through the first AlGaN layer, so that the source and the drain are in contact with the first GaN layer.

2. The enhancement HEMT of claim 1, further comprising:
a dielectric layer, which is formed on and in contact with the first AlGaN layer, wherein the dielectric layer lies between the P-type GaN layer and the drain in a channel direction; and
an adjustment drain, which is formed on and in contact with the dielectric layer;
wherein the dielectric layer and the adjustment drain entirely overlap each other, to form a stacked structure, and wherein a length of the stacked structure along the channel direction and a gap width between the stacked structure and the gate are determined according to a required operation reliability of the enhancement HEMT.

3. The enhancement HEMT of claim 1, further comprising:
a second AlGaN layer, which is formed below and in contact with the first GaN layer; and
a second GaN layer, which is formed below and in contact with the second AlGaN layer.

4. The enhancement HEMT of claim 3, wherein the source and the drain do not penetrate through the second AlGaN layer but stay in the first AlGaN layer, wherein a thickness of the second AlGaN layer is controlled so as to avoid generating a two-dimensional electron gas (2DEG) between the second AlGaN layer and the second GaN layer.

5. The enhancement HEMT of claim 3, wherein the source and drain further penetrate through the second AlGaN layer, so that the source and drain are in contact with the second GaN layer, whereby a 2DEG is generated between the second AlGaN layer and the second GaN layer by controlling a thickness of the second AlGaN layer.

6. The enhancement HEMT of claim 1, wherein the two insulation sidewalls include aluminum oxide (Al₂O₃), and wherein the two insulation sidewalls are formed via a self-alignment process step.

7. The enhancement HEMT of claim 2, wherein the dielectric layer includes P-type GaN, and wherein the dielectric layer and P-type GaN layer are formed via a same process step.

8. The enhancement HEMT of claim 2, wherein the adjustment drain and the drain are electrically connected to each other.

9. A manufacturing method of an enhancement HEMT, comprising steps of:
providing a substrate;
forming a first gallium nitride (GaN) layer on the substrate;
forming a first aluminum gallium nitride (AlGaN) layer on the first GaN layer, wherein the first AlGaN layer is in contact with the first GaN layer;
forming a trench in the first AlGaN layer, wherein the trench does not penetrate through the AlGaN layer;
forming an insulation sidewall via a self-alignment process step, wherein the insulation sidewall is in contact with and completely overlay two inner sidewalls of the trench;
forming a P-type GaN layer on the first AlGaN layer, wherein the P-type GaN layer is in contact with the first AlGaN layer, wherein a part of the P-type GaN layer fills into the trench;
forming a gate on the P-type GaN layer, wherein the gate is in contact with the P-type GaN layer, wherein the gate is configured to receive a gate voltage, so as to turn ON or turn OFF the enhancement HEMT; and
forming a source and a drain outside two sides of the gate, respectively, wherein the source and the drain penetrate through the first AlGaN layer, so that the source and the drain are in contact with the first GaN layer.

10. The manufacturing method of the enhancement HEMT of claim 9, further comprising following step:
forming a dielectric layer on the first AlGaN layer, wherein the dielectric layer is in contact with the first AlGaN layer, wherein the dielectric layer lies between the P-type GaN layer and the drain in a channel direction; and
forming an adjustment drain on the dielectric layer, wherein the adjustment drain is in contact with the dielectric layer;
wherein the dielectric layer and the adjustment drain entirely overlap each other, to form a stacked structure, and wherein a length of the stacked structure along the channel direction and a gap width between the stacked structure and the gate are determined according to a required operation reliability of the enhancement HEMT.

11. The manufacturing method of the enhancement HEMT of claim 9, further comprising:
forming a second AlGaN layer below the first AlGaN layer, wherein the second AlGaN layer is in contact with the first AlGaN layer
forming a second GaN layer below the second AlGaN layer, wherein the second GaN layer is in contact with the second AlGaN layer.

12. The manufacturing method of the enhancement HEMT of claim 11, wherein the source and the drain do not penetrate through the second AlGaN layer but stay in the first AlGaN layer, wherein a thickness of the second AlGaN layer is controlled so as to avoid generating a two-dimensional electron gas (2DEG) between the second AlGaN layer and the second GaN layer.

13. The manufacturing method of the enhancement HEMT of claim 11, wherein the source and drain further penetrate through the second AlGaN layer, so that the source and drain are in contact with the second AlGaN layer, whereby a 2DEG is generated between the second AlGaN layer and the second GaN layer by controlling a thickness of the second AlGaN layer.

14. The manufacturing method of the enhancement HEMT of claim 9, wherein the two insulation sidewalls include aluminum oxide (Al₂O₃), and wherein the two insulation sidewalls are formed via a self-alignment process step.

15. The manufacturing method of the enhancement HEMT of claim wherein the dielectric layer includes P-type GaN, and wherein the dielectric layer and P-type GaN layer are formed via a same process step.

16. The manufacturing method of the enhancement HEMT of claim wherein the adjustment drain and the drain are electrically connected to each other.
